(19) United States
(12) Patent Application Publication
(10) Pub. No.: US 2007/0111523 A1
(43) Pub. Date: May 17, 2007

(54) Process for conditioning conductive surfaces after electropolishing

(76) Inventors: Ismail Emesh, Gilbert, AZ (US); Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/283,112

(22) Filed: Nov. 17, 2005

(51) Int. Cl. H01L 21/44

(52) U.S. Cl. 438/687

(57) ABSTRACT

A method of conditioning an electropolished conductive layer of a substrate is disclosed, the conductive layer having impurities thereon. The conductive layer may be formed on a thin conductive film or barrier layer that coats one or more cavities formed on the substrate surface. The method comprises applying a first process solution onto the electropolished conductive layer to dissolve a portion thereof, and then applying a second process solution onto the conductive layer. The second process solution is preferably configured to charge and move the impurities away from the conductive layer. The substrate surface can then be rinsed to remove the first and second process solutions and the impurities.

### CROSS-REFERENCE TO RELATED APPLICATIONS

This application is related to U.S. Pat. No. 6,867,136, issued Mar. 15, 2005, and U.S. Pat. No. 6,943,112, issued Sep. 13, 2005.

### FIELD

The present invention generally relates to semiconductor integrated circuit technology and, more particularly, to process solutions for treating conductive surfaces after electropolishing or electroetching processes.

### BACKGROUND

Conventional semiconductor devices generally include a semiconductor substrate, usually a silicon substrate, and a plurality of sequentially formed dielectric layers and conductive paths or interconnects made of conductive materials. Interconnects are usually formed by filling a conductive material in trenches etched into the dielectric layers. In an integrated circuit, multiple levels of interconnect networks laterally extend with respect to the substrate surface. Interconnects formed in different layers can be electrically connected using vias or contacts. Wafer level integration is also possible using 3D-integration structures such as large vias. In this case, chips or wafers are interconnected through metal filled via structures that are typically wider than about 10 μm and deeper than about 20 μm.

The filling of a conductive material into features such as vias, trenches, pads or contacts, can be carried out by techniques such as electrochemical deposition or electroless deposition. In electrodeposition or electroplating methods, a conductive material, such as copper, is deposited over the substrate surface, including into such features. Copper is the material of choice for interconnect applications because of its low resistivity and good electromigration properties. After electrodeposition, a material removal technique is employed to planarize and remove the excess metal or overburden from the top surface, leaving conductors only in the features or cavities. In this way a network of interconnect structures are formed on the wafer surface.

The standard material removal technique that is most commonly used for the purpose of planarization and overburden removal is chemical mechanical polishing (CMP). During a CMP process, the surface of a substrate is polished by a polishing pad in the presence of a chemical solution while a force is applied onto the substrate to push the surface of the substrate against the polishing pad. In a typical CMP process, the copper layer thickness is reduced to about 100-200 nm in a first CMP station generally using slurries comprising abrasive particles. Then, this planarized wafer is transferred to a second CMP station where the remaining copper is removed all the way to the barrier layer surface using another slurry. The next step in the CMP process is barrier layer removal from the substrate surface, after which the conductive materials, e.g. remaining copper and barrier materials, are left within the cavities. Particles and chemical residues are then cleaned off of the wafer in a cleaning module. An alternative approach merges the second and third steps of the CMP process into a single step in which the 100-200 nm thick planarized copper layer is polished along with the barrier layer using a non-selective slurry.

Electropolishing or electrochemical mechanical polishing (which are also referred to as electroetching or electrochemical etching) are also attractive process options for copper removal.

Electrochemical mechanical polishing (ECMP) or planarization or etching removes copper by electrochemical dissolution while polishing the substrate with a pad at a reduced downforce compared to the conventional CMP. A typical downward force of 0.1-0.6 psi is applied during ECMP, which makes ECMP attractive for polishing metal layers formed on mechanically weak insulators such as ultra low-k dielectrics. An anodic potential is applied to the copper layer on the wafer surface in an electrolyte during ECMP with respect to an electrode which is also wetted by the electrolyte. ECMP stations are typically integrated parts of either copper CMP tools or systems or planar copper electrodepositon tools or systems. In a CMP tool, an ECMP process is utilized as a first planarization step of the overall copper removal process. In the CMP tool, wafers having electroplated copper layers are first planarized and thinned down to 100-200 nm thickness under low pressure in an ECMP station. Processing then continues in a first CMP station where the remaining copper is removed, and finally in a second CMP station where the barrier layer is removed, as explained above. Alternatively, as described above, the wafer is transferred into a CMP station after processing in the ECMP station to remove the remaining 100-200 nm thick copper along with the barrier layer using a non-selective slurry.

As integrated into a planar copper deposition tool (also referred to herein as a “plating tool”) the ECMP module or process station is used differently. In this case, a first process module in the planar copper deposition tool deposits copper and fills the cavities or features on the wafer surface with a conformal copper layer. The wafer with the conformal copper layer is then transferred within the same tool to an ECMP process module that planarizes and thins the deposited copper layer to about 100-200 nm thickness. What comes out of the plating tool is, therefore, a thin planar copper layer which may be annealed either within or outside the plating tool and sent to the CMP tool for removal of the remaining copper layer and the barrier layer as discussed above.

In an ECMP process, a copper coated wafer surface is pressed against a polishing pad while feeding an electrolyte to the surface. The electrolyte may contain a mixture of abrasive particles and chemicals, such as complexing agents, film forming agents or passivation agents, buffers and surfactants. Small amounts of residues of such chemicals and particles tend to remain on the electropolished surface after the ECMP planarization. These residues often cannot be rinsed off by water and contaminate the planarized copper surface. In some cases the electrolyte may not contain any particles, but the polishing action may cause microscopic portions of the pad material to break off or cause the abrasive particles to be removed from the pad. Microscopic particles from the electrolyte of the pad often cling to microscopic irregularities in the polished surface of a wafer. Since these ultra-fine particles often possess an electric charge, they may also adhere to the wafer surface via electrostatic, Van der Waals forces.

In the above described copper CMP tool, the ECMP process is performed using acidic (such as phosphoric acid based) electrolytes including abrasive particles and other chemicals such as corrosion suppressors like BTA. Such electrolytes are not compatible with the chemicals used in the following CMP process step, in which the planarized remaining copper is removed. Without an effective cleaning step between the ECMP and the CMP processes, residues, i.e., particles (microscopic or large) and chemicals such as phosphorus containing residues, are carried into the CMP environment and detonate the chemical mechanical polishing action on the copper layer and cause corrosion of copper-filled features on the wafer surface once the remaining copper is cleared and the barrier is exposed. This in turn forms a poor quality surface finish with micro defects and corrosion pits and causes high resistance and reliability problems, such as poor electromigration and stress migration, in the interconnect structure. Similar contamination concerns are also valid for the above mentioned planar copper electrodepositon tool or system. If not effectively cleaned, ECMP process residues left on the electropolished surface reduce the quality of the surface, cause corrosion of the surface, and cause cross contamination problems in subsequent process steps, such as anneal steps and CMP steps.

Thus, a need exists for processes for effectively cleaning the electropolished surfaces of semiconductor wafers and other workpieces after the ECMP processes.

### SUMMARY

In accordance with this need, embodiments of the present invention provides methods and apparatuses for conditioning an electropolished conductive surface of a substrate prior to subsequent process steps, such as annealing or CMP.

In one aspect, the present invention provides a method of conditioning an electropolished planar conductive layer of a substrate, the planar conductive layer including impurities thereon, wherein the impurities comprise particles and chemical residues. The method comprises spinning the substrate; and applying a first process solution onto the planar conductive layer while the substrate is spinning. The first process solution is configured to dissolve a predetermined portion of the planar conductive layer. The first process solution is also configured to dissolve the chemical residues and dislodge the particles.

In another aspect, the present invention provides a method of conditioning an electropolished planar conductive surface of a substrate, comprising spinning the substrate applying a process solution onto the planar conductive surface while the substrate is spinning to dissolve material on the surface and to form a conditioned planar surface.

In another aspect, the present invention provides a method of processing a conductive layer formed on a barrier layer on a wafer, the barrier layer coating a surface of the wafer and at least one cavity formed in the surface. In accordance with the method, an electropolishing process is applied to the conductive layer to form a planarized conductive layer, wherein the electropolishing process leaves impurities including particles and chemical residues on the planarized conductive layer. A predetermined thickness of the planarized conductive layer is dissolved to form a conditioned planar layer. Chemical mechanical polishing is applied to the conditioned planar layer until the barrier layer on the surface of the wafer is exposed.

In still another aspect, the present invention provides a method of processing a wafer, a conductive film lining a surface of the wafer and the interior of at least one cavity formed in the surface. According to the method, a conductive layer is electrodeposited on the conductive film. An electropolishing process is applied to the conductive layer to form a planarized conductive layer, wherein the electropolishing process leaves impurities on the planarized conductive layer, the impurities including particles and chemical residues. A predetermined thickness of the planarized conductive layer is dissolved by a conditioning process to form a conditioned planar layer. Chemical mechanical polishing is applied to the conditioned planar layer until at least a portion of the conductive film on the surface of the wafer is exposed.

For purposes of summarizing the invention and the advantages achieved over the prior art, certain objects and advantages of the invention have been described above and as further described below. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a schematic illustration of a wafer having a planarized copper layer;

FIG. 2A is a schematic illustration of a wafer having a non-planar copper layer deposited by an electrochemical deposition;

FIG. 2B is a schematic illustration of a wafer having a planar copper layer deposited by an electrochemical mechanical deposition;

FIG. 3 is a schematic illustration of the wafer shown in FIG. 1, wherein a conditioning process of the present invention has been applied to the planarized copper layer; and

FIGS. 4A-4B are schematic illustrations of an embodiment of a module having electropolishing and conditioning stations to carry out the process of the present invention.

### DETAILED DESCRIPTION

The present invention provides a conditioning process to treat a conductive surface of a wafer after the conductive surface is planarized by electropolishing. In a preferred embodiment, the conductive surface is formed of copper. However, other conductive materials can be used, such as other metals, alloys or compounds. While the following text describes the invention in the context of copper removal, skilled artisans will appreciate that other types of conductive materials can be used.

The conditioning process of the present invention cleans or prepares the copper conductive surfaces to form a conditioned surface to minimize or eliminate defects forming during subsequent process steps, for example an annealing step and/or a CMP process step. The conditioning process of the present invention may be performed using one or more process solutions. During the conditioning process, these process solutions remove or dissolve a predetermined top portion (e.g., a predetermined thickness) of an electropolished copper surface and dissolve or lift off residues, such as particles, chemicals and irregularities, that are left from the previous electropolishing process. When such conditioned copper surface is further processed using, for example, an annealing process and/or a copper CMP process, the presence of micro defects, particles and chemical residues in and on the resulting surface is substantially reduced.

The conditioning process of the present invention is applied to a wafer preferably after electropolishing by ECMP the copper surface in the above described planar copper electrodepositon tool or copper CMP tool. As described above in the Background section, in the planar copper electrodeposition tool, the copper is typically electrodeposited in an electrodeposition station and then the electrodeposited wafer is electropolished in the same system in an electropolishing station that processes the wafer surface by ECMP. In the copper CMP tool, an electrodeposited and annealed wafer is typically first electropolished by ECMP, and then the electropolished layer and the barrier layer are removed either in two CMP stations or one CMP station. Of course, the present invention can be used after any electropolishing process performed in any process tool.

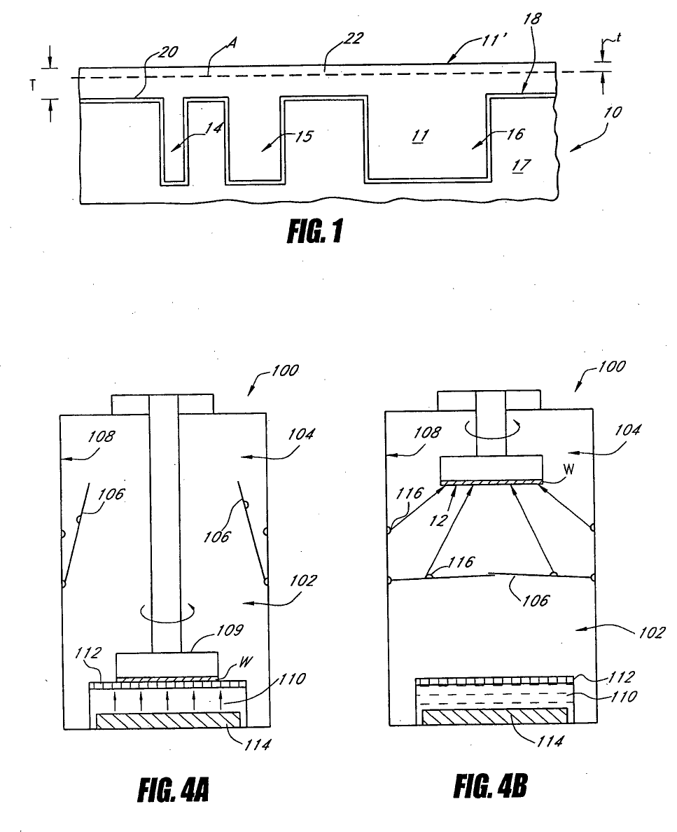

A conditioning process of one embodiment of the present invention will be illustrated with reference to FIGS. 1-4B. FIG. 1 shows a substrate 10 having a planarized conductive layer 11 with a planar surface 11′. In this embodiment, the planarized conductive layer 11 comprises a copper or copper alloy, although it may be any other conductive material such as Ag, Au, Pt, Cr, Ni and other metals or their alloys. Depending on the system that is being employed, the planarized copper layer 11 may be obtained by electropolishing exemplary copper layers 12 or 13 shown in FIGS. 2A and 2B. As shown in FIG. 2A, the copper layer 12 is a conformal or non-planar copper layer including an excess copper portion E1. The non-planar copper layer 12 may be deposited using a standard electrochemical deposition (ECD) process. Electropolishing of the excess copper E1 by an ECMP process forms the planarized copper layer 11. Copper layer 12 may be electropolished in a first station of a CMP tool or in a planar electrodeposition tool, as described above, or alternatively in another type of tool. As shown in FIG. 2B, the copper layer 13 is a planar copper layer including a planar excess copper portion E2. The planar copper layer 13 may be deposited using a planar deposition process such as electrochemical mechanical deposition (ECMD). Electropolishing of the planar excess copper E2 forms the planarized copper layer 11. Planar copper layer 13 may be electropolished in a copper electropolishing tool or in a CMP tool, as described above, or alternatively in another type of tool.

The illustrated substrate 10 includes small features 14 such as high aspect ratio trenches or vias; medium features 15 such as medium size trenches; and large features 16 such as large trenches. The features 14, 15, 16 are cavities formed in a dielectric layer 17.

The illustrated substrate 10 may be an exemplary portion on a semiconductor wafer, such as a silicon wafer. The dielectric layer 17 has a top surface 18. The features 14, 15, 16 as well as the top surface 18 of the dielectric layer 17 are coated with a barrier/glue or adhesion layer 20. The barrier layer 20 may be made of Ta, TaN, WN, WCN, combinations thereof, or any other materials or combinations of materials that are commonly used as barriers for copper deposition. Although not shown, a seed layer may be deposited over the barrier layer 20. However, specially designed more conductive barrier layers or nucleation layers such as ruthenium (Ru) layers do not need a seed layer. The planarized copper layer 11 fills the features 14, 15, 16 and extends on top of the substrate. The planarized copper layer 11 may have a thickness ‘T’ measured from a portion of the barrier layer 20 on the surface 18 to a top surface 11′ of the planarized copper layer 11. Once the electropolishing is over, the planarized copper layer 11 is conditioned using the conditioning process of the present invention, which is described below.

Referring to FIG. 1, in one embodiment, the conditioning process of the present invention may comprise multiple process steps. In a first step of the process, a top portion 22 of the planarized copper layer 11, which is depicted as the portion above the dotted line ‘A,’ is removed. The top portion 22 may have a predetermined thickness ‘t’ in the range of less than 160 nm, preferably less than 20 nm. In this embodiment, the top portion 22 is removed or dissolved by etching the planar copper surface 11′ by a first process solution S1 at an etch rate of, for example, about 10 nm/min. Etching the planar copper surface 11′ with the first process solution S1 effectively dislodges small particles left on the surface 11′, suspends them in the first solution S1, and also etches away any impurities or chemical residues present on the original surface 11′. The first process solution S1 may include: an acid or a complexing agent such as malic acid, malonic acid, citric acid or tartaric acid; a buffer solution such as ammonium oxalate, or any buffer solution suitable for a particular pH; an oxidizing agent such as hydrogen peroxide (H₂O₂); and a surfactant such as phytic acid. Further, ammonium hydroxide (NH₄OH) may be used to adjust the pH of the first process solution. The etch rate of the first process solution S1 can be fine-tunable by adjusting the concentrations of the oxidizing agent and the complexing agent. One example of a composition of the first solution S1 is: 1 to 10% malic acid by weight; 1 to 5% ammonium oxalate by weight; 0.01 to 1% phytic acid by weight; 0.1 to 2% H₂O₂ by volume; and NH₄OH in an amount sufficient to adjust the pH of the first process solution to 4-6.

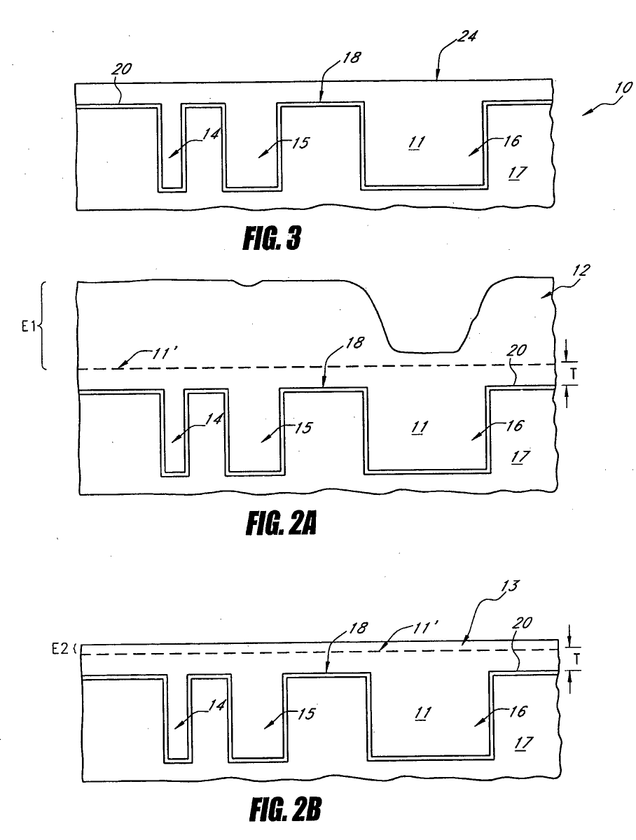

After completing the first step of the conditioning process, in a second process step, a second process solution S2 may be applied on the planarized copper layer 11 to make sure that any dislodged particles left thereon are removed from the surface. Application of the process solutions S1 and S2 form a conditioned surface 24 shown in FIG. 3.

The conditioned surface 24 is mainly formed during the application of the first solution S1 by dissolving the top surface portion 22 on which particles reside and dislodging and gathering the particles into the solution. In the next step, the second process solution S2 is preferably configured to charge the conditioned surface 24 and any remaining dislodged particles so that particles are repelled from the conditioned surface 24 and swept away with the flowing solution. Preferably there is no water rinsing step between applying the first process solution S1 and the second process solution S2 to the wafer surface although it is possible to include a water rinsing step. After applying the solution S2, there is preferably a final water rinsing step. The second process solution S2 may comprise: a complexing agent such as malic acid, malonic acid, citric acid or tartaric acid; a corrosion inhibitor such as BTA; and a reducing agent such as 1,2,3 trihydroxy benzene. It may also contain a surfactant such as phytic acid, poloxomer (L62). The pH of the solution can be adjusted by the addition of ammonium hydroxide or tetramethyl ammonium hydroxide. One example of a composition of the second solution S2 is: 1 to 10% citric acid by weight; 0.1 to 1% BTA by weight; 0.01 to 1% phytic acid by weight; 0.1 to 2% 1,2,3 trihydroxy benzene by weight; and NH₄OH in an amount sufficient to adjust the pH of the second process solution to 4-6.

Referring to FIG. 3, once the step of applying the second process solution S2 is complete, the conditioned surface 24 is preferably rinsed using a solution such as DI water to remove impurities and remaining particles from the conditioned surface 24. The rinsing step finalizes the process of forming a planarized surface substantially free from chemicals or particles. The rinsing solution, such as DI water, may contain a corrosion inhibitor or a surfactant to ensure the cleanliness of the conditioned surface. After the rinsing step, the substrate 10 is delivered to next process module for the next process step.

For the next step, if the electropolishing and the conditioning processes are performed in a CMP tool, the substrate can be delivered to a CMP station for further copper removal. If the electropolishing and the conditioning processes are performed in a copper deposition tool, the substrate can be sent to an anneal chamber within the system or taken out of the system and delivered to an anneal chamber and/or a CMP apparatus. Advantageously, no appreciable defects are formed during the process steps following the electropolishing or ECMP step, because the conditioned planar copper surface 24 is substantially free from particles and chemical residues of the ECMP step.

It should be noted that the conditioning step may also be used to further reduce the thickness of the electropolished and planarized copper surface. In this case, more copper is etched and dissolved during the conditioning step. For example, if the copper thickness is 200 nm after the ECMP step, preferably at least 1 nm, more preferably at least 5 nm, even more preferably at least 20 nm, and even more preferably 100-150 nm of this copper may be removed during the conditioning step. If 100-150 nm of the copper is removed during the conditioning step of the invention, then a planar copper layer with a thickness of 50-100 nm will be sent to the annealing chamber or to the CMP system or the CMP station. It is, in principle, also possible to remove all the copper from the wafer surface during the conditioning step, thereby exposing the barrier layer, which may then be removed by CMP.

Both electropolishing and conditioning processes may be performed in an exemplary electropolishing module 100 shown in FIG. 4A to electropolish and condition a wafer W. The module 100 may include two process stations; namely, an electropolishing station 102 and a conditioning station 104. Stations 102 and 104 are separated by movable separators 106 such as flaps attached on the inner walls 108 of the system 100. As such, in this embodiment, conditioning station 104 is positioned above the electropolishing station 102. By extending or retracting a wafer carrier 109 that holds the wafer W, the wafer W can be processed first in the electropolishing chamber 102, and then in the conditioning chamber 104 after closing the separators 106. The module 100 can replace ECMP stations used in the abovementioned copper CMP tools and copper electrodepositon tools. The module 100 facilitates application of two processes in a convenient manner. However, in any copper CMP tool or copper electrodepositon tool, a conditioning station or chamber may be in any suitable position with respect to the ECMP chamber, such as horizontally side-by-side.

The substrate 10 shown in FIGS. 1-3 a small portion of the wafer W. Therefore, the reference numbers for the substrate 10 from FIGS. 1-3 will be used to describe processing of the wafer W. In the electropolishing station 102, the excess copper layer shown in FIG. 2A or 2B is removed by an electropolishing process using an electropolishing electrolyte 110 and a polishing pad 112. In this embodiment, during the process, the wafer W is held by the wafer carrier 109, which may rotate and laterally move the surface of the excess copper layer E1 or E2 (see FIGS. 2A-2B) on the electropolishing pad 112 to form the planar copper surface 11′ (FIG. 1). The electropolishing pad 112 may include porosity or openings (not shown) allowing the electropolishing electrolyte 110 to contact an electrode 114 (cathode) and the conductive surface of the wafer W at the same time. During this process an electrical potential difference is preferably applied between the electrode 114 and the conductive surface of the wafer W, making the wafer surface anodic. The electropolishing electrolyte 110 of the present invention is preferably a known acidic solution that may include at least one of phosphoric acid, potassium phosphate and ammonium phosphate solutions.

With reference to FIG. 4B, after forming the planarized copper layer 11 on the wafer W, wafer carrier 109 with the wafer W is preferably retracted into the conditioning station 104 to perform the conditioning process. During stages of the conditioning process, the process solutions S1, S2 and the rinsing solution are delivered to the planar copper surface 11′ of the wafer W (preferably while the wafer W is rotating) using a suitable solution delivery means, such as one or more nozzles 116. Nozzles 116 can be placed on the separators 106 and the inner walls 108 of the system 100. In FIG. 4B, preferred directions of the flow of solution from the nozzles 116 are depicted by the arrows. The solutions are preferably delivered from solution supply tanks (not shown) controlled by an appropriate solution control system (not shown). In one exemplary process sequence, during the first conditioning process step, the first process solution S1 is delivered from the nozzles 116 to the planar copper surface 11′. At the second step of the process, the second process solution S2 is delivered to the planar copper surface 11′. As described above, the first and the second process steps form the conditioned planar surface 24 shown in FIG. 3. After forming the conditioned planar surface 24, the rinsing solution is applied from the nozzles 116 to rinse the wafer W. It should be noted that separate nozzles may be used to deliver the different solutions used in this overall process. Alternatively the same set of nozzles may be utilized for different solutions.

Although various preferred embodiments and the best mode have been described in detail above, those skilled in the art will readily appreciate that many modifications of the exemplary embodiment are possible without materially departing from the novel teachings and advantages of this invention.

What is claimed is:

1. A method of conditioning an electropolished planar conductive layer of a substrate, the planar conductive layer including impurities thereon, wherein the impurities comprise particles and chemical residues, the method comprising:
spinning the substrate; and
applying a first process solution onto the planar conductive layer while the substrate is spinning, the first process solution being configured to dissolve a predetermined portion of the planar conductive layer, the first process solution also configured to dissolve the chemical residues and dislodge the particles.

2. The method of claim 1, further comprising applying a second process solution onto the planar conductive layer, the second process solution being configured to charge and move the dislodged particles away from the planar conductive layer.

3. The method of claim 2, wherein applying the first and the second process solutions on the planar conductive layer forms a conditioned planar conductive layer.

4. The method of claim 1, wherein a composition of the first process solution comprises: 1 to 10% malic acid by weight; 1 to 5% ammonium oxalate by weight; 0.01 to 1% phytic acid by weight; 0.1 to 2% hydrogen peroxide by volume; and NH₄OH in an amount sufficient to adjust a pH of the first process solution to 4-6.

5. The method of claim 2, wherein a composition of the second process solution comprises: 1 to 10% citric acid by weight; 0.1 to 1% BTA by weight; 0.01 to 1% phytic acid by weight; 0.1 to 2% trihydroxy benzene by weight; and NH₄OH in an amount sufficient to adjust a pH of the second process solution to 4-6.

6. The method of claim 1, wherein a thickness of the predetermined portion of the planar conductive layer is at least 5 nm.

7. The method of claim 6, wherein the thickness of the predetermined portion is in the range of 100-150 nm.

8. The method of claim 1, wherein the planar conductive layer is made of copper.

9. The method of claim 2, further comprising, after said step of applying the second process solution, applying a rinsing solution to the conditioned planar surface.

10. The method of claim 1, wherein the particles comprise at least one of ceramic particles and polymeric particles.

11. A method of conditioning an electropolished planar conductive surface of a substrate, comprising:
spinning the substrate; and
applying a process solution onto the planar conductive surface while the substrate is spinning to dissolve material on the surface and to form a conditioned planar surface.

12. The method of claim 11, further comprising, after said step of applying the process solution, applying another process solution to move the dissolved material away from the conditioned planar surface.

13. The method of claim 11, further comprising, after said step of applying said another process solution, applying a rinsing solution to remove the dissolved material from the conditioned planar surface.

14. A method of processing a conductive layer formed on a barrier layer on a wafer, the barrier layer coating a surface of the wafer and at least one cavity formed in the surface, the method comprising:
applying an electropolishing process to the conductive layer to form a planarized conductive layer, wherein the electropolishing process leaves impurities including particles and chemical residues on the planarized conductive layer;
dissolving a predetermined thickness of the planarized conductive layer to form a conditioned planar layer; and
applying chemical mechanical polishing to the conditioned planar layer until the barrier layer on the surface of the wafer is exposed.

15. The method of claim 14, wherein the dissolving step comprises:
applying a first process solution onto the planarized conductive layer, the first process solution being configured to dissolve the predetermined thickness of the planarized conductive layer, the first process solution also configured to dissolve the chemical residues and at least a portion of the particles while dislodging remaining particles; and
applying a second process solution onto the planarized conductive layer, the second process solution being configured to charge and move the remaining particles away from the planarized conductive layer.

16. The method of claim 14, wherein, prior to the step of applying the electropolishing process, the conductive layer has a planar surface.

17. The method of claim 14, wherein, prior to the step of applying the electropolishing process, the conductive layer has a non-planar surface.

18. The method of claim 14, further comprising, after said step of applying chemical mechanical polishing, removing the barrier layer on the surface by applying chemical mechanical polishing.

19. The method of claim 14, further comprising annealing the conditioned planarized layer before said step of applying chemical mechanical polishing.

20. The method of claim 15, wherein a composition of the first process solution comprises: 1 to 10% malic acid by weight; 1 to 5% ammonium oxalate by weight; 0.01 to 1% phytic acid by weight; 0.1 to 2% hydrogen peroxide by volume; and NH₄OH in an amount sufficient to adjust a pH of the first process solution to 4-6.

21. The method of claim 15, wherein a composition of the second process solution comprises: 1 to 10% citric acid by weight; 0.1 to 1% BTA by weight; 0.01 to 1% phytic acid by weight; 0.1 to 2% trihydroxy benzene by weight; and NH₄OH in an amount sufficient to adjust a pH of the second process solution to 4-6.

22. The method of claim 14, wherein the predetermined thickness of the planarized conductive layer is at least 5 nm.

23. The method of claim 22, wherein the predetermined thickness of the planarized conductive layer is in the range of 100-150 nm.

24. The method of claim 14, wherein the conductive layer is made of copper.

25. The method of claim 15, further comprising, after said step of applying the second process solution and before said step of applying chemical mechanical polishing, applying a rinsing solution to the conditioned planar layer.

26. The method of claim 14, wherein the dissolving step comprises:
applying a first process solution onto the planarized conductive layer, the first process solution being configured to dissolve the predetermined thickness of the planarized conductive layer, the first process solution also configured to dissolve the chemical residues and at least a portion of the particles while dislodging remaining particles; and
applying a second process solution onto the planarized conductive layer, the second process solution having a pH substantially equal to a pH of the first process solution.

27. The method of claim 26, wherein said step of applying the second process solution occurs while the first process solution is on the planarized conductive layer, the second process solution being configured to charge and move the remaining particles away from the planarized conductive layer.

28. A method of processing a wafer, a conductive film lining a surface of the wafer and the interior of at least one cavity formed in the surface, the method comprising:
electrodepositing a conductive layer on the conductive film;
applying an electropolishing process to the conductive layer to form a planarized conductive layer, wherein the electropolishing process leaves impurities on the planarized conductive layer, the impurities including particles and chemical residues;
dissolving a predetermined thickness of the planarized conductive layer by a conditioning process to form a conditioned planar layer; and
applying chemical mechanical polishing to the conditioned planar layer until at least a portion of the conductive film on the surface of the wafer is exposed.

29. The method of claim 28, wherein the conditioning process comprises:
applying a first process solution onto the planarized conductive layer, the first process solution being configured to dissolve the predetermined thickness of the planarized conductive layer, the first process solution also configured to dissolve the chemical residues and dislodge the particles; and
applying a second process solution which is configured to charge and move the dislodged particles away from the planar conductive layer.

30. The method of claim 29, wherein the first process solution is configured to undercut and dislodge the particles.

31. The method of claim 28, wherein electrodepositing comprises electrochemical deposition, and wherein the conductive layer, prior to the step of applying the electropolishing process, has a non-planar surface.

32. The method of claim 28, wherein electrodepositing comprises electrochemical mechanical deposition, and wherein the conductive layer, prior to the step of applying the electropolishing process, has a planar surface.

33. The method of claim 28, further comprising annealing the conditioned planar layer before said step of applying chemical mechanical polishing.

34. The method of claim 29, wherein a composition of the first process solution comprises: 1 to 10% malic acid by weight; 1 to 5% ammonium oxalate by weight; 0.01 to 1% phytic acid by weight; 0.1 to 2% hydrogen peroxide by volume; and NH₄OH in an amount sufficient to adjust a pH of the first process solution to 4-6.

35. The method of claim 29, wherein a composition of the second process solution comprises: 1 to 10% citric acid by weight; 0.1 to 1% BTA by weight; 0.01 to 1% phytic acid by weight; 0.1 to 2% trihydroxy benzene by weight; and NH₄OH in an amount sufficient to adjust a pH of the second process solution to 4-6.

36. The method of claim 28, wherein the predetermined thickness of the planarized conductive layer is at least 5 nm.

37. The method of claim 36, wherein the predetermined thickness of the planarized conductive layer is in the range of 100-150 nm.

38. The method of claim 28, wherein the conductive layer is made of copper.

39. The method of claim 29, further comprising, after said step of applying the second process solution and before said step of applying chemical mechanical polishing, applying a rinsing solution to the conditioned planar surface.

40. The method of claim 28, wherein the conductive film is a barrier layer.

41. The method of claim 28, wherein the conductive film is a bi-layer including a barrier layer and a seed layer.

42. The method of claim 40, further comprising, after said step of applying chemical mechanical polishing, removing the barrier layer on the wafer surface by applying chemical mechanical polishing to the wafer surface.
